(19) United States
(12) Patent Application Publication
(10) Pub. No.: US 2025/0149458 A1
(43) Pub. Date: May 8, 2025

(54) SEMICONDUCTOR PACKAGE

(71) Applicant: Samsung Electronics Co., Ltd., Suwon-si (KR)

(72) Inventors: Eunkyeong Park, Suwon-si (KR); SANG SUB SONG, Suwon-si (KR); SEOKBEOM YONG, Suwon-si (KR)

(21) Appl. No.: 18/738,439

(22) Filed: Jun. 10, 2024

(30) Foreign Application Priority Data
Nov. 8, 2023 (KR) 10-2023-0153960

(51) Int. Cl. H01L 23/538; H01L 23/00; H01L 25/16; H10B 80/00

(52) U.S. Cl. CPC H01L 23/5386; H01L 23/5383; H01L 24/16; H01L 25/16; H01L 2224/16225; H10B 80/00

(57) ABSTRACT

A semiconductor package comprises an interconnection structure including a plurality of signal wires and a plurality of ground wires, wherein the plurality of signal wires and the plurality of ground wires are alternately arranged in the first horizontal direction and extend in the second horizontal direction intersecting with the first horizontal direction; and a first semiconductor chip and a second semiconductor chip on the interconnection structure, wherein the interconnection structure includes first regions under the first semiconductor chip and under the second semiconductor chip and a second region between the first regions, and the plurality of signal wires connect the first semiconductor chip and the second semiconductor chip; wherein each of the plurality of signal wires has a first width in the first horizontal direction in the first region and a second width in the first horizontal direction in the second region, and the second width is greater than the first width.

### CROSS-REFERENCE TO RELATED APPLICATION

This application claims priority to and the benefit of Korean Patent Application No. 10-2023-0153960 filed in the Korean Intellectual Property Office on Nov. 8, 2023, the entire contents of which are incorporated herein by reference.

### BACKGROUND OF THE INVENTION

The present disclosure relates to a semiconductor package.

Recently, an interconnection structure has been required to support high performance of an electronic product. The interconnection structure electrically connects semiconductor chips to each other in a semiconductor package. The interconnection structure includes signal wires, ground wires, and the dielectric material. The dielectric material surrounds the signal wires and the ground wires. The interconnection structure has a function for exchanging signals with semiconductor chips through the signal wires and the ground wires.

When a low frequency signal is transmitted through the interconnection structure, reducing the effective length of the signal wire affects the signal transmission characteristics. However, the design arrangement of the signal wire and ground wire, the dielectric constant of the dielectric material in the interconnection structure and other variables do not significantly affect the signal transmission characteristics. However, when a high frequency signal is transmitted through the interconnection structure, the design arrangement of the signal wire and the ground wire in the interconnection structure, the dielectric constant of the dielectric material in the interconnection structure and other variables intricately and significantly influence the signal transmission characteristics. In order to transmit signals at high speed, it is necessary to secure a wide bandwidth. To satisfy this high-frequency condition, an interconnection structure with a signal-signal-signal (SSS) wire structure or a ground-signal-ground (GSG) wire structure within one routing layer has been developed.

The SSS wire structure in an interconnection structure has the advantage that it may include as many signal wires as possible. But, since there is no ground pattern between adjacent signal wires, crosstalk between adjacent signal wires is a drawback so that the signal integrity (SI) is degraded.

The GSG wire structure has the advantage that crosstalk may be improved by including ground patterns between adjacent signal wires. But, since ground patterns occupy a significant amount of area of the interconnection structure, the width of the signal wire is required to be decreased, so as to increase the resistance. Further the space between the signal wire and the ground wire is decreased, so as to increase undesirable parasitic capacitance. Accordingly, there is a drawback that the signal integrity (SI) is degraded due to RC delay.

### SUMMARY OF THE INVENTION

An interposer includes a GSG wire structure including signal wires and ground wires and includes first regions under the semiconductor chips and a second region between the first regions. The signal wires and the ground wires are arranged alternately in the first horizontal direction and extend in the second horizontal direction intersecting with the first horizontal direction.

In the above-described interposer, it is possible to increase the width of the first horizontal direction of the signal wire in the second region.

In the above-described interposer, it is possible to increase the width of the first horizontal direction of the signal wire in the second region and increase the spacing of the first horizontal direction between the signal wire and the ground wire in the second region.

A semiconductor package according to an embodiment comprises an interposer including a plurality of signal wires and a plurality of ground wires, wherein the plurality of signal wires and the plurality of ground wires are arranged alternately in the first horizontal direction and extend in the second horizontal direction intersecting with the first horizontal direction; and a first semiconductor chip and a second semiconductor chip on the interposer, wherein the interposer includes first regions under the first semiconductor chip and under the second semiconductor chip and a second region between the first regions, and the plurality of signal wires connect the first semiconductor chip and the second semiconductor chip; wherein each of the plurality of signal wires has a first width in the first horizontal direction in the first regions and a second width in the first horizontal direction in the second region, and the second width is greater than the first width.

A semiconductor package according to an embodiment comprises an interposer including a plurality of signal wires and a plurality of ground wires, wherein the plurality of signal wires and the plurality of ground wires are arranged alternately in the first horizontal direction and extend in the second horizontal direction intersecting with the first horizontal direction; and a first semiconductor chip and a second semiconductor chip on the interposer, wherein the interposer includes first regions under the first semiconductor chip and under the second semiconductor chip and a second region between the first regions, and the plurality of signal wires connect the first semiconductor chip and the second semiconductor chip; wherein each of the plurality of signal wires has a first width in the first horizontal direction in the first regions and a second width in the first horizontal direction in the second region, and the second width is greater than the first width and wherein each of the plurality of signal wires is spaced apart by a first distance in the first regions and by a second distance in the second region from the ground wire an adjacent one of the plurality of ground wires, and the second distance is greater than the first distance.

A semiconductor package according to an embodiment comprises an interposer including a first signal routing layer including a plurality of first signal wires and a plurality first ground wires, and a first ground routing layer including a ground wire structure, and disposed at least one position of upper part and lower part of the first signal routing layer, wherein the plurality of first signal wires and the plurality of first ground wires are alternately arranged in a first horizontal direction and extend in a second horizontal direction intersecting the first horizontal direction, and a first semiconductor chip and a second semiconductor chip on the interposer, wherein the interposer include first regions under the first semiconductor chip and under the second semiconductor chip and a second region between the first regions and the plurality of first signal wires connect the first semiconductor chip and the second semiconductor chip, wherein each signal wire among the plurality of first signal wires has a first width in the first horizontal direction in the first regions and a second width in the first horizontal direction in the second region, and the second width is greater than the first width.

The interposer has a GSG wire structure including signal wires and ground wires, and includes first regions under the semiconductor chips and a second region between the first regions. Signal wires and ground wires are arranged alternately in the first horizontal direction and extend in the second horizontal direction intersecting the first horizontal direction.

In the above-described interposer, the signal integrity SI characteristic may be improved by increasing the width of the first horizontal direction of the signal wire in the second region.

In the above-described interposer, it is possible to reduce RC delay and improve signal integrity SI characteristics by increasing the width of the first horizontal direction of the signal wire in the second region and increasing the distance of first horizontal direction between the signal wire and the ground wire in the second region.

### BRIEF DESCRIPTION OF THE DRAWINGS

FIG. 1 is a cross-sectional view illustrating a semiconductor package of an embodiment.

FIG. 2 is a plan view illustrating an interconnection structure of an embodiment.

FIG. 3 is a cross-sectional view showing the first region of the GSG wire structure of an embodiment of the interconnection structure of FIG. 2.

FIG. 4 is a cross-sectional view showing the second region of the GSG wire structure of embodiment of the interconnection structure of FIG. 2.

FIG. 5 is a cross-sectional view showing the first region of the GSG wire structure of another embodiment of the interconnection structure of FIG. 2.

FIG. 6 is a cross-sectional view showing the second region of the GSG wire structure of another embodiment of the interconnection structure of FIG. 2.

FIG. 7 is a cross-sectional view showing the first region of the GSG wire structure of another embodiment of the interconnection structure of FIG. 2.

FIG. 8 is a cross-sectional view showing the second region of the GSG wire structure of another embodiment of the interconnection structure of FIG. 2.

FIG. 9 is a cross-sectional view showing the first region of the GSG wire structure of another embodiment of the interconnection structure of FIG. 2.

FIG. 10 is a cross-sectional view showing the second region of the GSG wire structure of another embodiment of the interconnection structure of FIG. 2.

FIG. 11 is a plan view illustrating an interconnection structure of another embodiment.

FIG. 12 is a cross-sectional view showing the second region of the GSG wire structure of an embodiment of the interconnection structure of FIG. 11.

FIG. 13 is a cross-sectional view showing the second region of the GSG wire structure of another embodiment of the interconnection structure of FIG. 11.

FIG. 14 is a cross-sectional view showing the second region of the GSG wire structure of another embodiment of the interconnection structure of FIG. 11.

FIG. 15 is a cross-sectional view showing the second region of the GSG wire structure of another embodiment of the interconnection structure of FIG. 11.

### DETAILED DESCRIPTION OF THE EMBODIMENTS

Hereinafter, with reference to the accompanying drawings, an embodiment of the present disclosure will be described in detail so that a person of an ordinary skill in the art could easily carry out the present disclosure.

The present invention may be implemented in several different forms but is not limited to the embodiments described herein. In order to clearly explain the present disclosure in the drawings, parts not related to the description are omitted, and the same reference numerals are assigned to the same or similar element throughout the specification. It should be noted that items described in the singular herein, may be provided in plural, as can be seen in the various figures from the context in which they are described.

In addition, the size and thickness of each component shown in the drawing are arbitrarily shown for better understanding and ease of description, so the present disclosure is not necessarily limited to what is shown. Throughout this specification, when a part is “coupled” to another element, it may include not only “directly connected” but also “indirectly connected” with other members in between. In addition, unless explicitly described to the contrary, the word “comprise”, and variations such as “comprises” or “comprising”, will be understood to imply the inclusion of stated elements but not the exclusion of any other elements.

In addition, it will be understood that when an element such as a layer, film, region, or substrate is referred to as being “on” another element, it can be directly on the other element or intervening elements may also be present. In contrast, when an element is referred to as being “directly on” another element, there are no intervening elements present. In addition, being “above” or “on” a reference part means being positioned above or below the reference part, and does not necessarily mean being positioned “above” or “on” it in the opposite direction of gravity.

In addition, throughout the specification, the phrase “on a plane” means when an object portion is viewed from above, and the phrase “on a cross-section” means when a cross-section taken by vertically cutting an object portion is viewed from the side. In the present application, the references X, Y, and Z will be used to denote a first horizontal direction, a second horizontal direction, and a vertical direction, respectively, each of which may be perpendicular to the other two directions.

Ordinal numbers such as “first,” “second,” “third,” etc. may be used simply as labels of certain elements, steps, etc., to distinguish such elements, steps, etc. from one another. Terms that are not described using “first,” “second,” etc., in the specification, may still be referred to as “first” or “second” in a claim. In addition, a term that is referenced with a particular ordinal number (e.g., “first” in a particular claim) may be described elsewhere with a different ordinal number (e.g., “second” in the specification or another claim).

Hereinafter, a semiconductor package of an embodiment will be described with reference to drawing.

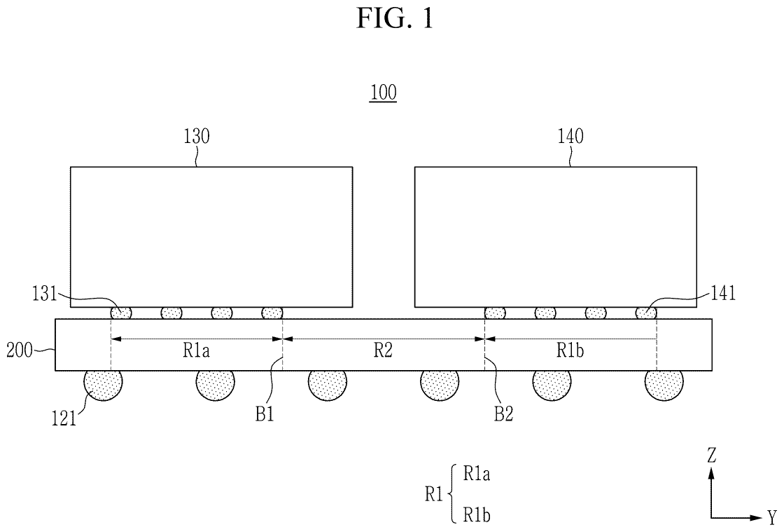

FIG. 1 is a cross-sectional view illustrating a semiconductor package 100 of an embodiment.

Referring to FIG. 1, a semiconductor package 100 includes an interconnection structure 200, a first semiconductor chip 130, and a second semiconductor chip 140. In an embodiment, the semiconductor package 100 may be at least part of a 2.1D semiconductor package or a 2.5D semiconductor package, but the invention is not limited thereto. The 2.5D packaging may refer to a technology of horizontally placing semiconductor chips on a silicon interposer, and the 2.1D packaging may refer to a technology of horizontally placing semiconductor chips on a RDL (redistribution layer).

A semiconductor chip manufactured by applying a fine process may be electrically coupled with a package substrate in order to exchange signals with other semiconductor chips. However, the package substrate has a relatively large circuit line width compared to the semiconductor chip to which the fine process is applied. In order to connect the semiconductor chip, to which the fine process is applied, with the package substrate, an intermediate medium may be required to alleviate the difference in line width between a semiconductor chip, to which the fine process is applied, and the package substrate. As such an intermediate medium, an interconnection structure 200, to which a fine process is applied, may be used. The interconnection structure 200 may have pattern widths greater than that of the semiconductor chips. The interconnection structure 200 may have a pattern widths less than that of the substrate. Spacing between the patterns of the interconnection structure 200 may be greater than that of the semiconductor chips and less than that of the substrate.

A semiconductor package typically includes one or more semiconductor chips stacked on a package substrate. The package substrate may be, for example, a PCB (printed circuit board) substrate, or a semiconductor substrate. The package substrate may be the bottommost substrate in a package. It should be apparent that the term “substrate” may be used to refer to the package substrate (e.g., the bottommost substrate of a semiconductor package). It should also be appreciated that the substrate to which the interconnection structure 200 connects need not be the bottommost substrate in a package, but may be an intermediate substrate (such as an interposer separate from the interconnection structure 200).

The interconnection structure 200 is disposed between the substrate (not shown in the drawings) and the first semiconductor chip 130 and disposed between the substrate and the second semiconductor chip 140. In an embodiment of the invention, the interconnection structure 200 electrically connects the first semiconductor chip 130 to the substrate in the vertical direction and connects the second semiconductor chip 140 to the substrate in the vertical direction. The interconnection structure 200 electrically connects the first semiconductor chip 130 to the second semiconductor chip 140 in the second horizontal direction. The interconnection structure 200 functions as an intermediate medium comprising an intermediate wire connecting the first semiconductor chip 130 having a fine pitch I/O and the second semiconductor chip 140 having a fine pitch I/O to a normal pitch I/O. In an embodiment, the interconnection structure 200 may include or be a silicon interposer. In an embodiment, the interconnection structure 200 may include or be a redistribution interposer. The interconnection structure 200 is electrically connected to the substrate by connection members 121

In an embodiment of the invention, the interconnection structure 200 may be electrically connected to the package substrate by third connection members 121. The vertical direction (Z direction) may be perpendicular to the upper and lower surfaces of the interconnection structure 200. The term “fine pitch I/O” refers to input/output terminals having relatively a small size and/or having a relatively narrow spacing (relatively smaller pitch) between the input/output terminals. The term “normal pitch I/O” refers to input/output terminals having a relatively large size and/or having a relatively wide spacing (relatively larger pitch) between the input/output terminals. The input/output terminals may be conductive terminals connected to internal wiring of the semiconductor chips (or the semiconductor package), and may transmit signals and/or supply voltages between an internal wiring and/or internal circuit of the device (or the semiconductor package) and an external source. The input/output terminals may be provided on or near an external surface of the device (or the semiconductor package) and may have a shape of plate, a bump or a solder ball (often larger than a corresponding surface area of the internal wiring to which they are connected) to promote connection to a an external wiring. Utilizing the interconnection structure 200 as an intermediate medium is helpful to alleviate the issue of line width difference. Accordingly, the first semiconductor chip 130 and the second semiconductor chip 140 may be both electrically connected to each other and to the substrate having a normal pitch I/O.

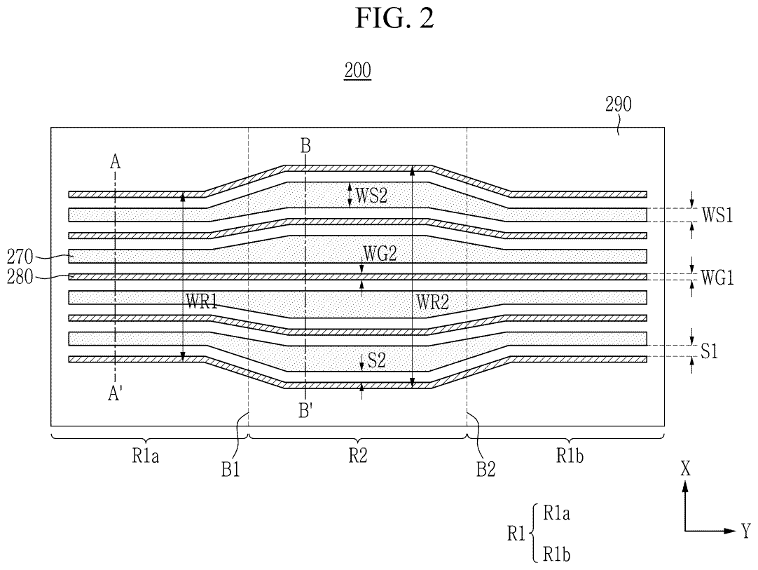

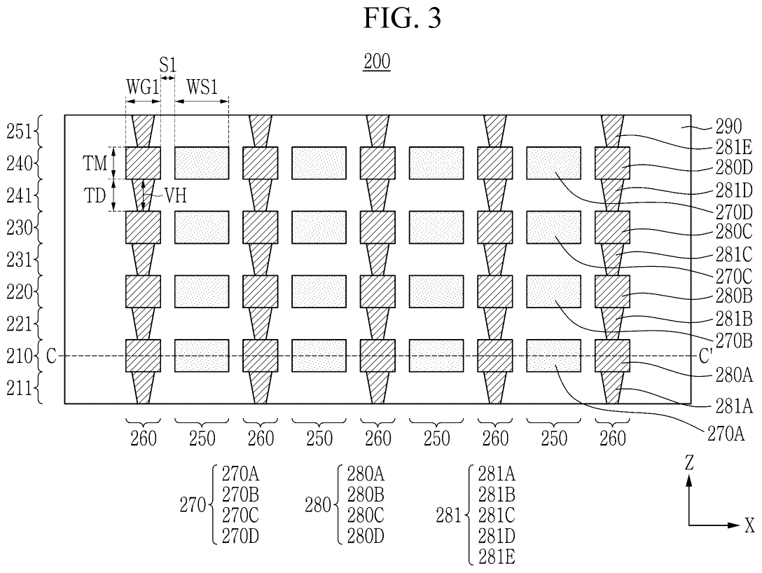

FIG. 2 is a plan view illustrating an interconnection structure 200 in a routing layer (shown in FIG. 3) according to an embodiment.

Referring to FIGS. 1 and 2, first connection members 131 may be connected to the first semiconductor chip 130, and second connection members 141 may be connected to the second semiconductor chip 140. The interconnection structure 200 includes first region R1 and a second region R2. The first region R1 may include a first subsidiary region R1a and a second subsidiary region R1b. The first subsidiary region R1a may be disposed under the first semiconductor chip 130 and the second subsidiary region R1b may be disposed under the second semiconductor chip 140. The second region R2 may be under the region between the first semiconductor chip 130 and the second semiconductor chip 140. The first subsidiary region R1a under the first semiconductor chip 130 may be the corresponding region between at least a portion (i.e., some numbers) of the connection members disposed on the outermost side in the second horizontal direction (Y direction) among the first connection members 131 connected to the first semiconductor chip 130. The second subsidiary region R1b under the second semiconductor chip 140 may be the corresponding region between at least a portion (i.e., some numbers) of the connection members disposed on the outermost side in the second horizontal direction (Y direction) among the second connection members 141 connected to the second semiconductor chip 140. Unless context indicates otherwise, it should be appreciated that a plural form “first regions R1” will be understood to refer to at least the first subsidiary region R1a and the second subsidiary region R1b. The second region R2 may be the corresponding region between a portion of the first connection members 131 positioned closest to the second semiconductor chip 140 among the first connection members 131 connected to the first semiconductor chip 130 and a portion of the second connection members 141 positioned closest to the first semiconductor chip 130 among the second connection members 141 connected to the second semiconductor chip 140. In an embodiment, the footprint of the first regions R1a is included in (e.g., encompassed by) the footprint of the first semiconductor chip 130 and the footprint of the second region R1b ins included in (encompassed by) the foot print of the second semiconductor chip 140, but the invention is not limited thereto. The first semiconductor chip 130 may be electrically connected to the second semiconductor chip 140 though at least a portion of the first connection members and though at least a portion of second connection members 141. The plurality of the first connection members 131 may have two opposite sides in the second horizontal direction (Y direction). Between the two sides of the plurality of the first connection members 131, the closer side to the second semiconductor chip 140 may be aligned to a dashed line B1 on a plane. Similarly, between two sides of the plurality of the second connection members 141 in the second horizontal direction (Y direction), the closer side to the first semiconductor chip 130 may be aligned to a dashed line B2 on a plane. The dashed lines B1 and B2 may be parallel to the first direction (X direction). The dashed lines B1 and B2 may be the boundaries between the first regions R1 and the second region R2.

The first semiconductor chip 130 is disposed on the interconnection structure 200. The first semiconductor chip 130 is electrically connected to the interconnection structure 200 through the first connection members 131. The first semiconductor chip 130 is electrically connected to the second semiconductor chip 140 through the interconnection structure 200. In an embodiment, the first semiconductor chip 130 may include a system on chip (SoC). In an embodiment, the first semiconductor chip 130 may include at least one of a central processing unit (CPU) and a graphic processing unit (GPU).

The second semiconductor chip 140 is disposed on the interconnection structure 200. Alternatively, the number of the second semiconductor chip 140 may be one or more. The second semiconductor chip 140 is electrically connected to the interconnection structure 200 through the second connection members 141. The second semiconductor chip is electrically connected to the first semiconductor chip 130 through the interconnection structure 200. In an embodiment, the second semiconductor chip 140 may include a high bandwidth memory (HBM). In the embodiments described herein, each of the first and second semiconductor chips 130 and 140 may be replaced by a plurality of stacked chips. For example, the second semiconductor chip 140 may be replaced by a plurality of second semiconductor chips, such as a plurality of stacked DRAM chips.

Referring to FIG. 2, the interconnection structure 200 may include a ground-signal-ground (GSG) wire structure. The GSG wire structure includes a plurality of connection wires. The plurality of connection wires may include signal wires 270, ground wires 280, and dielectric material 290. The signal wires 270 and the ground wires 280 are alternately arranged in the first horizontal direction (X direction). The connection wires shown in FIG. 2 are disposed within a routing layer which will be described in later.

The signal wires 270 extend in a second horizontal direction (Y direction) intersecting the first horizontal direction (X direction). In an embodiment, the signal wires 270 may be provided in an elongated shape. In the first region R1, the signal wire 270 has a first width WS1 in the first horizontal direction (X direction) and, in the second region R2, the signal wire 270 has a second width WS2 in the first horizontal direction (X direction). The second width WS2 may be greater than the first width WS1. In an embodiment, the first width WS1 may be about 1.5 μm. In an embodiment, the second width WS2 may be about 4 μm.

The ground wires 280 extend in a second horizontal direction (Y direction) intersecting with the first horizontal direction (X direction). In an embodiment, the ground wires 280 may be provided in an elongated shape. In the first region R1, the ground wire 280 has a third width WG1 in the first horizontal direction (X direction), and in the second region R2, the ground wire 280 has a fourth width WG2 in the first horizontal direction (X direction). The third width WG1 may be equal to the fourth width WG2.

In the first region R1, each of the signal wires 270 is spaced apart from neighboring one of the ground wires 280 by a first distance S1. In the second region R2, each of the signal wires 270 is spaced apart from neighboring one of the ground wires 280 by a second distance S2. The first distance S1 may be equal to the second distance S2. In an embodiment, the first distance S1 may be about 1.0 μm. In an embodiment, the second width WG2 may be about 1.0 μm. In an embodiment of the invention, the width of the signal wire 270 may be gradually increased in a direction from the first region R1 and the second region R2 at an interface region between the first region R1 and the second region R2.

It should be understood that the width of a wiring is in a direction perpendicular to the extending direction of the wiring, where the extending direction is the path of the wiring (e.g., corresponding to the current path provided by the wiring). As the entire path of a wiring may not be linear, it should be appreciated that the extending direction of a wiring may change along the length of the wiring (and likewise, the width direction changes). For a linear segment of wiring, the length of the wiring segment in the extending direction is greater than its width (perpendicular to that extending direction). Unless the context clearly indicates otherwise, it will be understood that the terms “width” should be considered to be a “minimum width” of the element. A “space” or “spacing” between elements refers to the shortest dimension between two adjacent elements on a plane. Unless the context clearly indicates otherwise, it will be understood that the terms “space” should be considered to be a “minimum space” dimension between the two adjacent elements. Terms such as “same,” or “equal,” as used herein do not necessarily mean an exactly identical orientation, layout, location, shape, size, composition, amount, or other measure, but are intended to encompass nearly identical within acceptable variations that may occur, for example, due to manufacturing processes. The term “substantially” may be used herein to emphasize this meaning, unless the context or other statements indicate otherwise.

In the first region R1 and the second region R2, as a result of testing under the condition that the third width WG1 and the fourth width WG2 in the first horizontal direction (X direction) of each of the ground wires 280 is the same, the first distance S1 may be the same as the second distance S2, and the second width WS2 in the first horizontal direction (X direction) of the signal wires 270 is greater than the first width WS1, the eye opening value is increased. By implementing the dimensional relationship described above, an eye opening value 73% has been achieved, while an eye opening value in a reference test was 68%. In contrast, the second width WS2 was the same as the first width WS1 in the reference test. Therefore, according to the present disclosure, the signal integrity (SI) characteristic of the semiconductor package may be improved.

Referring to FIG. 2, in an embodiment, the number of the signal wires 270 may be more than the number of ground wires 280 within a routing layer. For example, the number of the signal wires 270 may be one more than the number of ground wires 280 within a routing layer.

In an embodiment, the plurality of the connection wires has a third width WR1 and a fourth width WR2 in the X direction, in the first region R1 and the second region R2, respectively. The third width WR1 is less than the fourth width WR2 within the routing layer. In another embodiment, each of the third widths WR1 in the first and second subsidiary regions R1a and R1b may be different to each other, so that the first subsidiary region R1a may have greater width than the second subsidiary region R1b within the routing layer.

The envelope of the plurality of the connection wires may form a symmetrical shape on a horizontal plane. For example, the connection wires within a routing layer may be arranged to be substantially symmetrical with respect to a central plane, which may be extending in the Y direction and the Z direction.

The signal wires 270 may be connected to an I/O latches of the semiconductor chips 130 and 140 to latch information (data, address, commands), where the I/O latches may be part of an I/O interface of the semiconductor chips.

The term “ground wires” will be understood as wires that provide a desired reference potential (e.g., zero or low voltage of 0.5 volts, e.g.) which need not be zero volts.

FIG. 3 is a cross-sectional view showing the first region R1 of the GSG wire structure of the interconnection structure 200 of FIG. 2 according to an embodiment. FIG. 3 is a cross-sectional view showing the interconnection structure 200 taken along line A-A′ of FIG. 2. FIG. 2 is a plan view illustrating the interconnection structure 200 taken along line C-C′ of FIG. 3.

Reference to FIG. 3, the interconnection structure 200 includes a vertical strip line structure and a dielectric material 290 surrounding the vertical strip line.

The vertical strip line structure includes first vertical structures 250 and second vertical structures 260. The vertical strip line structure includes first to fourth routing layers 210, 220, 230 and 240. The vertical strip line structure includes first to fifth connection layers 211, 221, 231, 241 and 251. Accordingly, FIG. 2 is a plan view illustrating the first routing layers 210. The vertical strip line structure includes the signal wires 270, the ground wires 280, and vias 281. The signal wires 270 includes first signal wires 270A, second signal wires 270B, third signal wires 270C, and fourth signal wires 270D. The number of signal wires is not limited thereto, and the interconnection structure 200 according to the present disclosure may include more or less signal wires. The first signal wire 270A, the second signal wire 270B, the third signal wire 270C, and the fourth signal wire 270D are disposed to overlap each other in each of the first vertical structures 250 on a plane. Each of the signal wires 270 routes a different signal from the rest of the signal wires. Each of the signal wires 270 is separated from the rest of the signal wires.

The ground wires 280 includes first ground wires 280A, second ground wires 280B, third ground wires 280C, and fourth ground wires 280D. The number of ground wires is not limited thereto, and the interconnection structure 200 according to the present disclosure may include more or less ground wires. The vias 281 includes a first via 281A, a second via 281B, a third via 281C, a fourth via 281D, and a fifth via 281E. The number of vias is not limited hereto, and the interconnection structure 200 according to the present disclosure may include more or less vias. The first via 281A, the first ground wire 280A, the second via 281B, the second ground wire 280B, the third via 281C, the third ground wire 280C, the fourth via 281D, the fourth ground wire 280D, and the fifth via 281E are disposed to overlap each other in each of the second vertical structures 260 on a plane.

The first vias 281A are positioned in the first connection layer 211. The first vias 281A may be disposed under the first ground wires 280A. The first via 281A electrically connects the first ground wire 280A to the substrate (not shown). The first connection layer 211 has a height TD in the Z direction. The first vias 281A have a height VH in the Z direction. The height VH is equal to the height TD. In an embodiment, the first vias 281A may be provided in a polygon or circular shape in the cross-section of the horizontal direction.

The reference characters S1, S2, WG1, WG2, WS1, WS2, TM, TD and VH are used herein to describe how a dimension may be measured. In the drawings, though the reference characters S1, S2, WG1, WG2, WS1, WS2, TM, TD and VH are shown only for a portion of the vertical structures and/or a portion of routing layers, it should be appreciated that the reference characters may be applicable to any other same or similar elements in other vertical structures and/or routing layers. However, using the same reference characters does not necessarily mean that the values of the dimensions are same to each other, unless the context clearly indicates otherwise.

First signal wires 270A and first ground wires 280A are positioned in the first routing layer 210. The first signal wires 270A and the first ground wires 280A may be alternately arranged in the first horizontal direction (X direction). The first signal wires 270A and the first ground wires 280A have a height TM in the vertical direction (Z direction). The first signal wire 270A is spaced apart from the neighboring first ground wire 280A in the first horizontal direction (X direction) with a distance of S1. The first signal wires 270A and the first ground wires 280A are not electrically connected to each other, but are separated.

Each of the first signal wires 270A has a first width WS1 in the first horizontal direction (X direction). Each of the first signal wires 270A may be not electrically connected to each other, but are separated. Each of the first signal wires 270A may be electrically connected to a substrate. Each of the first signal wires 270A is electrically connected to the first semiconductor chip 130 or the second semiconductor chip 140.

Each of the first ground wires 280A has a third width WG1 in the first horizontal direction (X direction). Each of the first ground wires 280A is disposed between the first via 281A and the second via 281B and electrically connects the second via 281B to the first via 281A. Within the first routing layer 210, the third width WG1 and the fourth width WG2 in the first horizontal direction (X direction) of each of the ground wires 280 may be the same, the first distance S1 may be the same as the second distance S2, and the second width WS2 in the first horizontal direction (X direction) of the signal wires 270 may be greater than the first width WS1.

The second vias 281B are positioned in the second connection layer 221. The second vias 281B are disposed between the first ground wires 280A and the second ground wires 280B. The second via 281B electrically connects the second ground wire 280B to the first ground wire 280A. The second connection layer 221 has a height TD in the vertical direction (Z direction). The second vias 281B have a height VH in the vertical direction (Z direction). The height VH is equal to the height TD. In an embodiment, the second vias 281B may be provided in a polygon or circular shape in the cross-section of the horizontal direction.

The second signal wires 270B and the second ground wires 280B are positioned in the second routing layer 220. The second signal wires 270B and the second ground wires 280B may be alternately arranged in the first horizontal direction (X direction). The second signal wires 270B and the second ground wires 280B have a height TM in Z direction. The second signal wire 270B is spaced apart from the neighboring second ground wire 280B in the first horizontal direction (X direction) with a distance of S1. The second signal wires 270B and the second ground wires 280B are not electrically connected to each other, but are separated.

Each of the second signal wires 270B has a first width WS1 in the first horizontal direction (X direction). Each of the second signal wires 270B may be not electrically connected to each other, but are separated. Each of the second signal wires 270B may be electrically connected to a substrate. At least a portion of the second signal wires 270B is electrically connected to the first semiconductor chip 130 or the second semiconductor chip 140.

Each of the second ground wires 280B has a third width WG1 in the first horizontal direction (X direction). Each of the second ground wires 280B is disposed between the second via 281B and the third via 281C, and electrically connects the third via 281C to the second via 281B.

The third vias 281C are positioned in the third connection layer 231. The third vias 281C are disposed between the second ground wires 280B and the third ground wires 280C. The third via 281C electrically connects third ground wire 280C to second ground wire 280B. The third connection layer 231 has a height TD in the vertical direction Z direction. The third vias 281C have a height VH in the vertical direction (Z direction). The height VH is equal to the height TD. In an embodiment, the third vias 281C may be provided in a polygon or circular shape in the cross-section of the horizontal direction.

Third signal wires 270C and third ground wires 280C are positioned in the third routing layer 230. The third signal wires 270C and the third ground wires 280C may be alternately arranged in the first horizontal direction (X direction). The third signal wires 270C and the third ground wires 280C have a height TM in the vertical direction (Z direction). The third signal wire 270C is spaced apart from the neighboring third ground wire 280C in the first horizontal direction (X direction) with a distance of S1. Third signal wires 270C and third ground wires 280C are not electrically connected to each other, but are separated.

Each of the third signal wires 270C has a first width WS1 in the first horizontal direction (X direction). Each of the third signal wires 270C may be not electrically connected to each other, but are separated. Each of the third signal wires 270C may be electrically connected to the substrate. Each of the third signal wires 270C is electrically connected to the first semiconductor chip 130 or the second semiconductor chip 140.

Each of the third ground wires 280C has a third width WG1 in the first horizontal direction (X direction). Each of the third ground wire 280C is disposed between third via 281C and fourth via 281D, and electrically connects the fourth via 281D to third via 281C.

The fourth vias 281D are positioned in the fourth connection layer 241. The fourth vias 281D are disposed between the third ground wires 280C and the fourth ground wires 280D. The fourth via 281D electrically connects the fourth ground wire 280D to the third ground wire 280C. The fourth connection layer 241 has a height TD in the vertical direction Z direction. The fourth vias 281D have a height VH in the vertical direction (Z direction). The height VH is equal to the height TD. In an embodiment, the fourth vias 281D may be provided in a polygon or circular shape in the cross-section of the horizontal direction.

The fourth signal wires 270D and the fourth ground wires 280D are positioned in the fourth routing layer 240. The fourth signal wires 270D and the fourth ground wires 280D may be alternately arranged in the first horizontal direction (X direction). The fourth signal wires 270D and the fourth ground wires 280D have a height TM in the vertical direction (Z direction). The fourth signal wire 270D is spaced apart from the neighboring fourth ground wire 280D in the first horizontal direction (X direction) with a distance of S1. The fourth signal wires 270D and the fourth ground wires 280D are not electrically connected to each other, but are separated.

Each of the fourth signal wires 270D has a first width WS1 in the first horizontal direction (X direction). Each of the fourth signal wires 270D is not electrically connected to each other, but are separated. Each of the fourth signal wires 270D may be electrically connected to the substrate. Each of the fourth signal wires 270D may be electrically connected to the first semiconductor chip 130 or the second semiconductor chip 140.

Each of the fourth ground wires 280D has a third width WG1 in the first horizontal direction (X direction). Each of the fourth ground wires 280D is disposed between the fourth via 281D and the fifth via 281E, and electrically connects the fifth via 281E to the fourth via 281D.

The fifth vias 281E are positioned in the fifth connection layer 251. The fifth vias 281E are disposed above the fourth ground wires 280D. The fifth via 281E is electrically connected to the fourth ground wires 280D. The fifth connection layer 241 has a height TD in the vertical direction Z direction. The fifth vias 281E have a height VH in the vertical direction (Z direction). The height VH is equal to the height TD. In an embodiment, the fifth vias 281E may be provided in a polygon or circular shape in the cross-section of the horizontal direction.

The dielectric material 290 surrounds and insulates the signal wires 270, the ground wires 280, and the vias 281. In an embodiment in which the interconnection structure 200 is a silicon interposer, the dielectric material 290 may include silicon or silicon oxide. In an embodiment in which the interconnection structure 200 is a redistribution interposer, the dielectric material 290 is a photo imageable dielectric (PID).

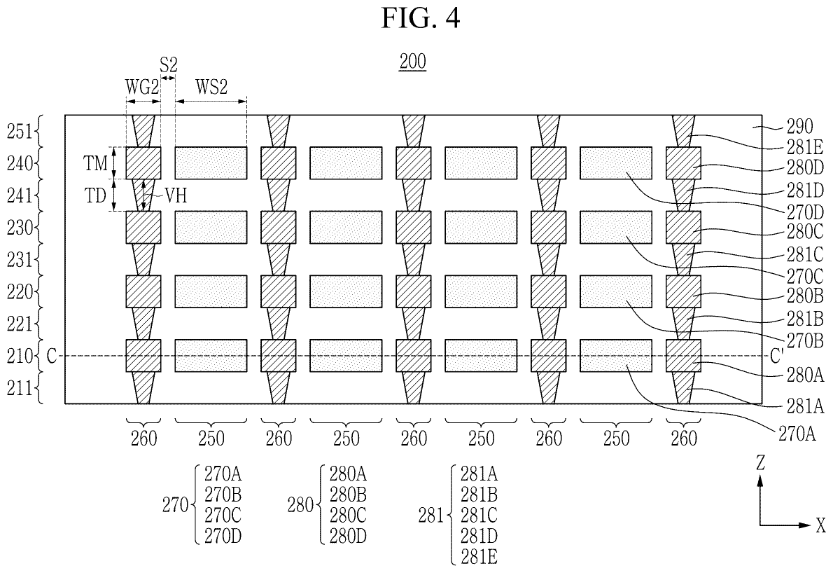

FIG. 4 is a cross-sectional view showing the second region of the GSG wire structure of an embodiment of the interconnection structure of FIG. 2. FIG. 4 is a cross-sectional view showing the interconnection structure 200 taken along line B-B′ of FIG. 2. FIG. 2 is a plan view illustrating the interconnection structure 200 taken along line C-C′ of FIG. 4.

Referring to FIGS. 3 and 4, in the first horizontal direction (X direction), the second width WS2 of the signal wire 270 may be greater than the first width WS1. In the first horizontal direction (X direction), the fourth width WG2 of ground wire 280 may be equal to the third width WG1. In the first horizontal direction (X direction), the second distance S2 may be equal to the first distance S1.

In addition to the above description, the description for signal wires 270, ground wires 280, and vias 281 described with respect to FIG. 3 may be applied to the description for signal wires 270, ground wires 280, and vias 281 in FIG. 4.

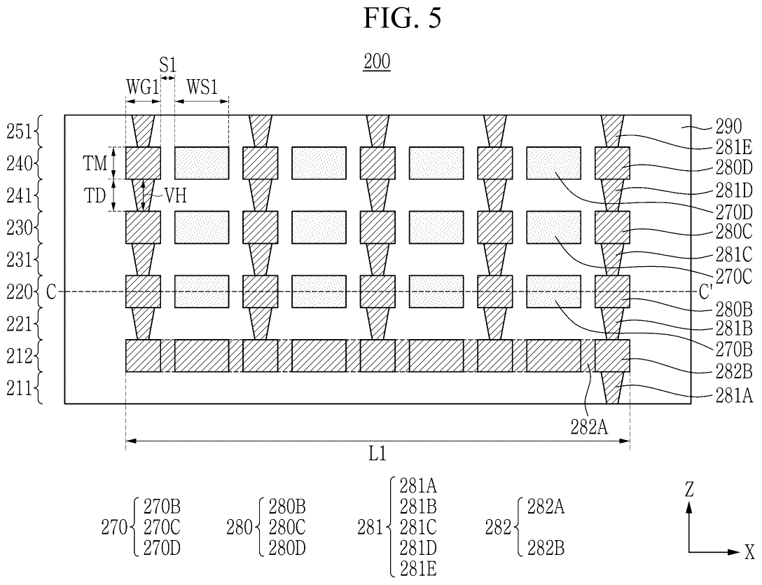

FIG. 5 is a cross-sectional view showing the first region R1 of the GSG wire structure of another embodiment of the interconnection structure 200 of FIG. 2. FIG. 5 is a cross-sectional view showing the interconnection structure 200 taken along line A-A′ of FIG. 2. FIG. 2 is a plan view illustrating the interconnection structure 200 taken along line C-C″ of FIG. 5.

Referring to FIG. 5, the interconnection structure 200 includes a ground routing layer 212. The ground routing layer 212 is the lowest one among the routing layers in the interconnection structure 200.

A ground routing layer 212 includes a ground wire structure 282 (also described as “ground wiring layer 282”). The ground wire structure 282 includes first subsidiary part 282A extending in a first horizontal direction (X direction) and second subsidiary part 282B extending in a second horizontal direction (Y direction). The first subsidiary part 282A and the second subsidiary part 282B are continuously and integrally formed. In an embodiment, the ground wire structure 282 may be provided in a mesh shape. In an embodiment, the first subsidiary part 282A may have a first length L1 in the first horizontal direction (X direction). The ground wire structure 282 is disposed between the first via 281A and the second via 281B and electrically connects the second via 281B to the first via 281A.

In addition to the above description, the description for signal wires 270, ground wires 280, and vias 281 described with respect to FIG. 3 may be applied to the description for signal wires 270, ground wires 280, and vias 281 in FIG. 5.

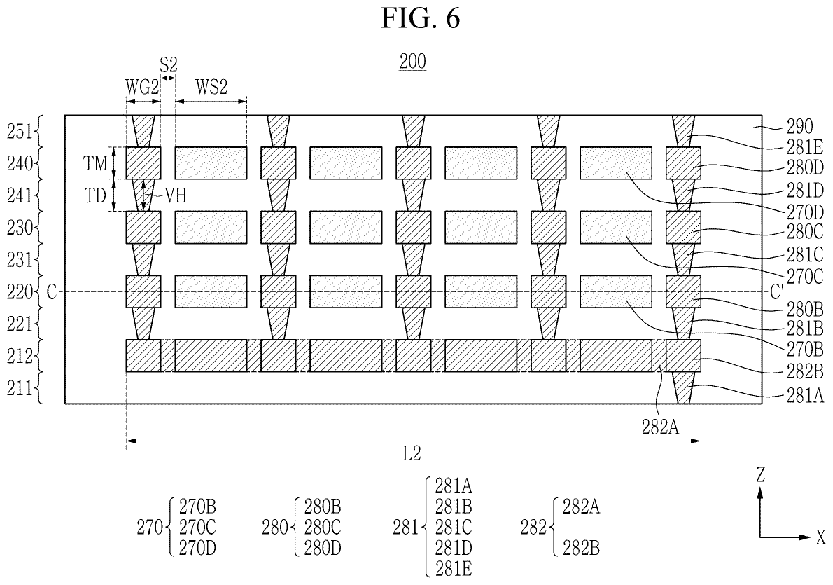

FIG. 6 is a cross-sectional view showing the second region R2 of the GSG wire structure of another embodiment of the interconnection structure 200 of FIG. 2. FIG. 6 is a cross-sectional view showing the interconnection structure 200 taken along line B-B′ of FIG. 2. FIG. 2 is a plan view illustrating the interconnection structure 200 taken along line C-C′ of FIG. 6.

Referring to FIG. 5 and FIG. 6, in the first horizontal direction (X direction), a second width WS2 of the signal wire 270 may be greater than a first width WS1. In the first horizontal direction (X direction), a fourth width WG2 of the ground wire 280 may be equal to a third width WG1. In the first horizontal direction (X direction), a second distance S2 may be equal to a first distance S1. In the first horizontal direction (X direction), a second length L2 of the first subsidiary part 282A in the second region R2 may be longer than the first length L1 of the first subsidiary part 282A in the second region R1.

In addition to the above description, the description for signal wires 270, ground wires 280, vias 281, and ground wire structure 282 described with respect to FIG. 5 may be applied to the description for signal wires 270, ground wires 280, vias 281, and ground wire structure 282 in FIG. 6.

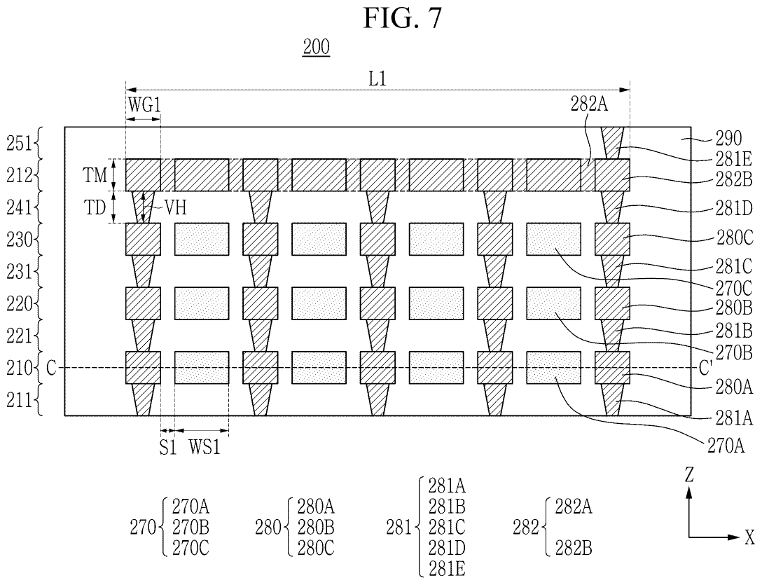

FIG. 7 is a cross-sectional view showing the first region R1 of the GSG wire structure of another embodiment of the interconnection structure 200 of FIG. 2. FIG. 7 is a cross-sectional view showing the interconnection structure 200 taken along line A-A′ of FIG. 2. FIG. 2 is a plan view illustrating the interconnection structure 200 taken along line C-C′ of FIG. 7.

Referring to FIG. 7, the interconnection structure 200 includes a ground routing layer 212. The ground routing layer 212 is the topmost one among the routing layers in the interconnection structure 200. According to the embodiment of the present disclosure, the ground routing layer 212 may be disposed more close to the first semiconductor chip 130 and the second semiconductor chip 140 by placing the ground routing layer 212 on top of the interconnection structure 200.

A ground routing layer 212 includes a ground wire structure 282 (i.e., ground wiring layer). The ground wire structure 282 includes first subsidiary part 282A extending in a first horizontal direction (X direction) and second subsidiary part 282B extending in a second horizontal direction (Y direction). The first subsidiary part 282A and the second subsidiary part 282B are continuously and integrally formed. In an embodiment, the ground wire structure 282 may be provided in a mesh shape. In an embodiment, the first subsidiary part 282A may have a first length L1 in the first horizontal direction (X direction). The ground wire structure 282 is disposed between the fourth via 281D and fifth via 281E, and electrically connects the fifth via 281E to the fourth via 281D.

In addition to the above description, the description for signal wires 270, ground wires 280, vias 281, and ground wire structure 282 described with respect to FIG. 5 may be applied to the description for signal wires 270, ground wires 280, vias 281, and ground wire structure 282 described in FIG. 7.

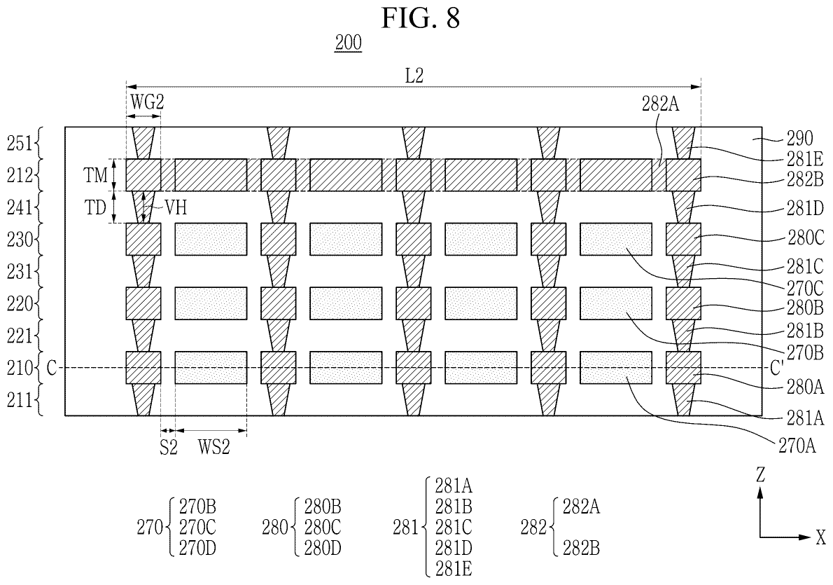

FIG. 8 is a cross-sectional view showing the second region R2 of the GSG wire structure of another embodiment of the interconnection structure 200 of FIG. 2. FIG. 8 is a cross-sectional view showing the interconnection structure 200 taken along line B-B′ of FIG. 2. FIG. 2 is a plan view illustrating the interconnection structure 200 taken along line C-C′ of FIG. 7.

Referring to FIG. 7 and FIG. 8, in the first horizontal direction (X direction), a second width WS2 of the signal wire 270 may be greater than a first width WS1. In the first horizontal direction (X direction), a fourth width WG2 of the ground wire 280 may be equal to a third width WG1. In the first horizontal direction (X direction), a second distance S2 may be equal to a first distance S1. In the first horizontal direction (X direction), a second length L2 in the second region R2 may be longer than the first length L1 in the second region R1.

In addition to the above description, the description for signal wires 270, ground wires 280, vias 281, and ground wire structure 282 described with respect to FIG. 7 may be applied to the description for signal wires 270, ground wires 280, vias 281, and ground wire structure 282 in FIG. 8.

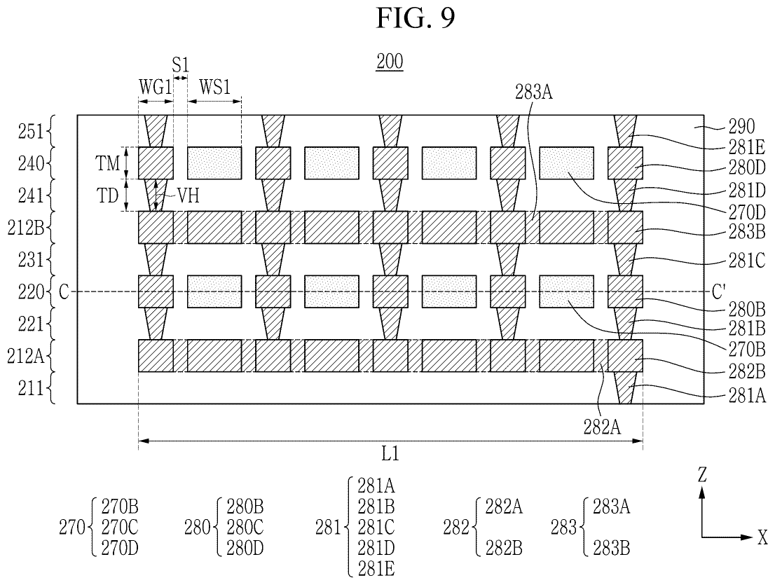

Referring to FIG. 9, the interconnection structure 200 includes a first ground routing layer 212A and a second ground routing layer 212B. The first ground routing layer 212A is the lowest one among the routing layers in the interconnection structure 200. The second ground routing layer 212B is disposed between third and fourth connection layers 231 and 241. The first ground routing layer 212A includes a first ground wire structure 282 (i.e., first ground wiring layer). The first ground wire structure 282 includes first subsidiary part 282A extending in a first horizontal direction (X direction) and second subsidiary part 282B extending in a second horizontal direction (Y direction). First subsidiary part 282A and second subsidiary part 282B are continuously and integrally formed. In an embodiment, the first ground wire structure 282 may be provided in a mesh shape. In an embodiment, the first subsidiary part 282A may have a first length L1 in the first horizontal direction (X direction). The first ground wire structure 282 is disposed between the first via 281A and the second via 281B and electrically connects the second via 281B to the first via 281A.

The second ground routing layer 212B may include a second ground wire structure 283 (i.e., second ground wiring layer). The second ground wire structure 283 includes third wires 283A extending in a first horizontal direction (X direction) and fourth wires 283B extending in a second horizontal direction (Y direction). The third wires 283A and fourth wires 283B are continuously and integrally formed. In an embodiment, the second ground wire structure 283 may be provided in a mesh shape. In an embodiment, the third wires 283A may have the first length L1 in the first horizontal direction (X direction). The second ground wire structure 283 is disposed between the third via 281C and the fourth via 281D and electrically connects the fourth via 281D to the third via 281C.

The second ground routing layer 212B may include a second ground wire structure 283 (i.e., second ground wiring layer). The second ground wire structure 283 includes third wires 283A extending in a first horizontal direction (X direction) and fourth wires 283B extending in a second horizontal direction (Y direction). The third wires 283A and fourth wires 283B are continuously and integrally formed. In an embodiment, the second ground wire structure 283 may be provided in a mesh shape. In an embodiment, the third wires 283A may have the first length L1 in the first horizontal direction (X direction). The second ground wire structure 283 is disposed between the third via 281C and the fourth via 281D and electrically connects the fourth via 281D to the third via 281C.

In addition to the above description, the description for signal wires 270, ground wires 280, vias 281, first ground wire structure 282, and second ground wire structure described with respect to FIG. 7 may be applied the description for signal wires 270, ground wires 280, vias 281, first ground wire structure 282, and second ground wire structure 283 in FIG. 9.

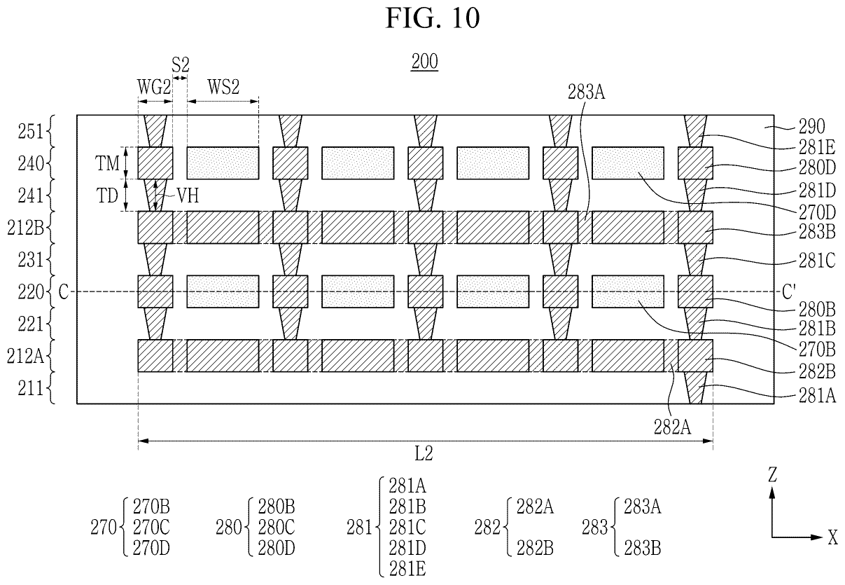

FIG. 10 is a cross-sectional view showing the second region R2 of the GSG wire structure of another embodiment of the interconnection structure 200 of FIG. 2. FIG. is a cross-sectional view showing the interconnection structure 200 taken along line B-B′ of FIG. 2. FIG. 2 is a plan view illustrating the interconnection structure 200 taken along line C-C′ of FIG. 10.

Referring to FIG. 9 and FIG. 10, in the first horizontal direction (X direction), a second width WS2 of the signal wire 270 may be greater than a first width WS1. In the first horizontal direction (X direction), a fourth width WG2 of ground wire 280 may be equal to a third width WG1. In the first horizontal direction (X direction), a second distance S2 may be equal to the first distance S1. In the first horizontal direction (X direction), a second length L2 may be longer than the first length L1.

In addition to the above description, the description for signal wires 270, ground wires 280, vias 281, first ground wire structure 282, and second ground wire structure 283 described with respect to FIG. 9 may be applied to the description for signal wires 270, ground wires 280, vias 281, first ground wire structure 282, and second ground wire structure 283 in FIG. 10.

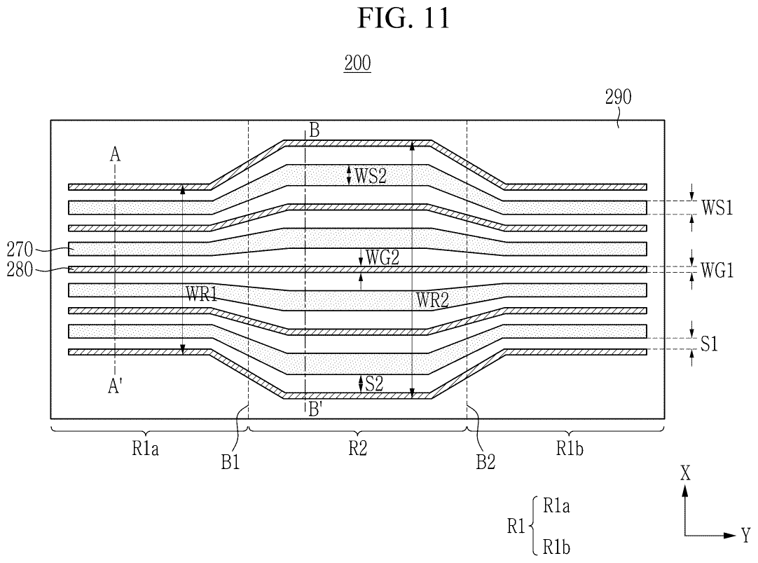

FIG. 11 is a top plan view illustrating an interconnection structure 200 of an embodiment.

Referring to FIG. 11, the interconnection structure 200 includes a plurality of connection wires. The plurality of connection wires may include signal wires 270, ground wires 280, and a dielectric material 290. The signal wires 270 and the ground wires 280 may be arranged alternately in the first horizontal direction (X direction). The connection wires shown in FIG. 11 are disposed within a routing layer which will be described later.

The signal wires 270 extend in a second horizontal direction (Y direction) intersecting the first horizontal direction (X direction). In an embodiment, the signal wires 270 may be provided in an elongated shape. In the first region R1, the signal wire 270 has a first width WS1 in the first horizontal direction (X direction), and in the second region R2, the signal wire 270 has a second width WS2 in the first horizontal direction (X direction). The second width WS2 may be greater than the first width WS1. In an embodiment, the first width WS1 may be about 1.5 μm. In an embodiment, the second width WG2 may be about 2.8 μm.

The ground wires 280 extend in a second horizontal direction (Y direction) intersecting the first horizontal direction (X direction). In an embodiment, the ground wires 280 may be provided in an elongated shape. In the first region R1, the ground wire 280 has a third width WG1 in the first horizontal direction (X direction), and in the second region R2, the ground wire 280 has a fourth width WG2 in the first horizontal direction (X direction). The third width WG1 may be equal to the fourth width WG2.

In the first region R1, each of the signal wires 270 is spaced apart from neighboring one of the ground wires 280 by a first distance S1. In the second region R2, each of the signal wires 270 is spaced apart from neighboring one of the ground wires 280 by a second distance S2. The second distance S2 may be greater than the first distance S1. In an embodiment, the first distance S1 may be about 1.0 μm. In an embodiment, the second width WG2 may be about 1.6 μm. In order to minimize the RC delay, the difference between the second distance S2 and the first distance S1 may be adjusted to be smaller than the difference between the second width WS2 and the first width WS1.

In first region R1 and second region R2, as a result of testing under the condition that the third width WG1 and the fourth width WG2 in the first horizontal direction (X direction) of each of the ground wires 280 is the same, the second distance S2 may be greater than the first distance S1, and the second width WS2 in the first horizontal direction (X direction) of the signal wires 270 is greater than the first width WS1, the eye opening value is increased. By implementing the dimensional relationship described above, an eye opening value 73% has been achieved, while the eye opening value in the reference test described previously.

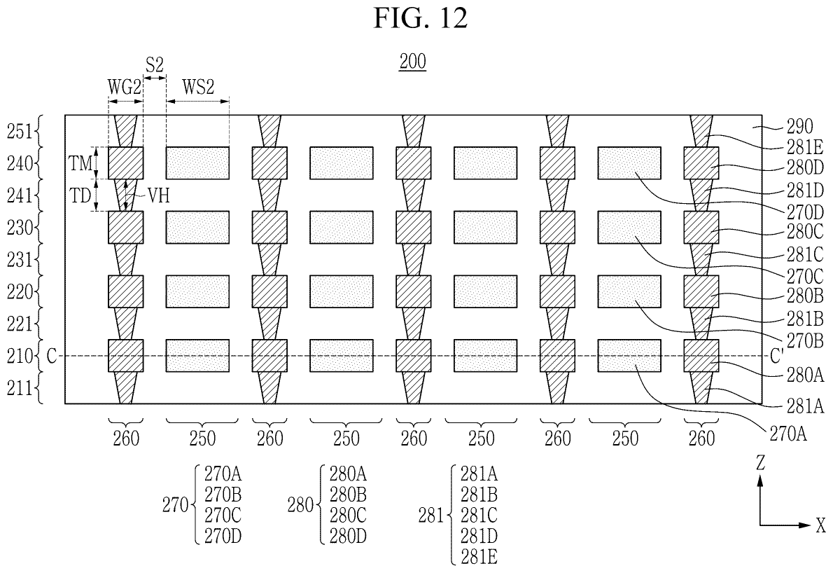

Referring to FIG. 12 in an embodiment, the number of the signal wires 270 may be more than the number of ground wires 280 within a routing layer. For example, the number of the signal wires 270 may be one more than the number of ground wires 280 within a routing layer. In an embodiment, the plurality of the connection wires has a third width WR1 and a fourth width WR2 in the X direction, in the first region R1 and the second region R2, respectively. The third width WR1 is less than the fourth width WR2 within the routing layer. In another embodiment, each of the third widths WR1 in the first and second subsidiary regions R1a and R1b may be different to each other, so that the first subsidiary region R1a may have greater width than the second subsidiary region R1b within the routing layer. The plurality of the connection wires may be a symmetrical shape on a plane. For example, the connection wires within a routing layer may be arranged to be substantially symmetrical with respect to a central plane, which may be extending in the Y direction and the Z direction. For example, the shape of the connection wires within a routing layer may be arranged to be substantially symmetrical in the second region R2 with respect to a central plane, which may be extending in the X direction and the Z direction.

FIG. 12 is a cross-sectional view showing the second region of the GSG wire structure of an embodiment of the interconnection structure of FIG. 11. The description shown and described with respect to FIG. 3 may be applied equally to the first region R1 of the GSG wire structure corresponding to FIG. 12.

Referring to FIG. 3 and FIG. 12, a second width WS2 of the signal wire 270 may be greater than a first width WS1 in the first horizontal direction (X direction). In the first horizontal direction (X direction), a fourth width WG2 of the ground wire 280 may be equal to a third width WG1. In the first horizontal direction (X direction), a second distance S2 may be greater than a first distance S1.

In addition to the above description, the description for signal wires 270, ground wires 280, and vias 281 described with respect to FIG. 4 may be applied to the description for signal wires 270, ground wires 280, and vias 281 in FIG. 12.

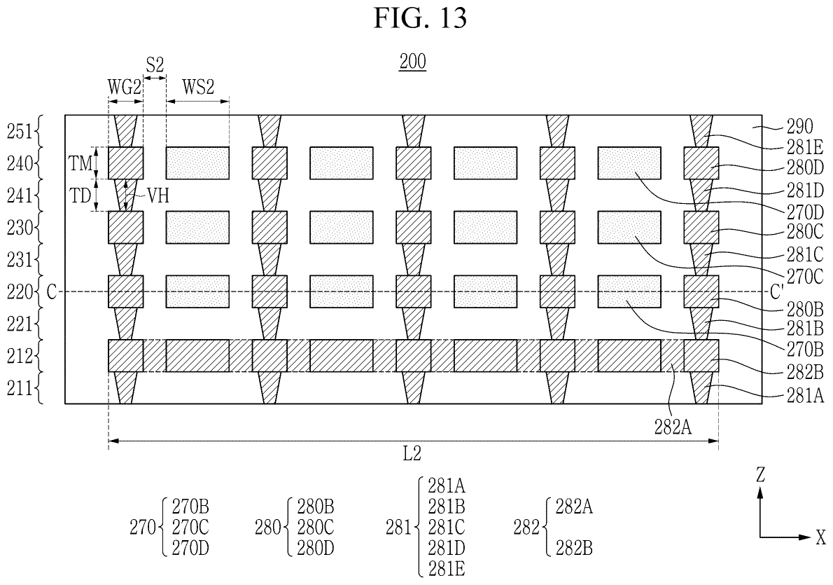

FIG. 13 to FIG. 15 are cross-sectional views showing the second region R2 of the GSG wire structure of the interconnection structure of FIG. 11 according to other embodiments. The description of FIG. 5, FIG. 7, and FIG. 9 may be equally applied to the first region R1 of the GSG wire structure corresponding to FIG. 13 to FIG. 15.

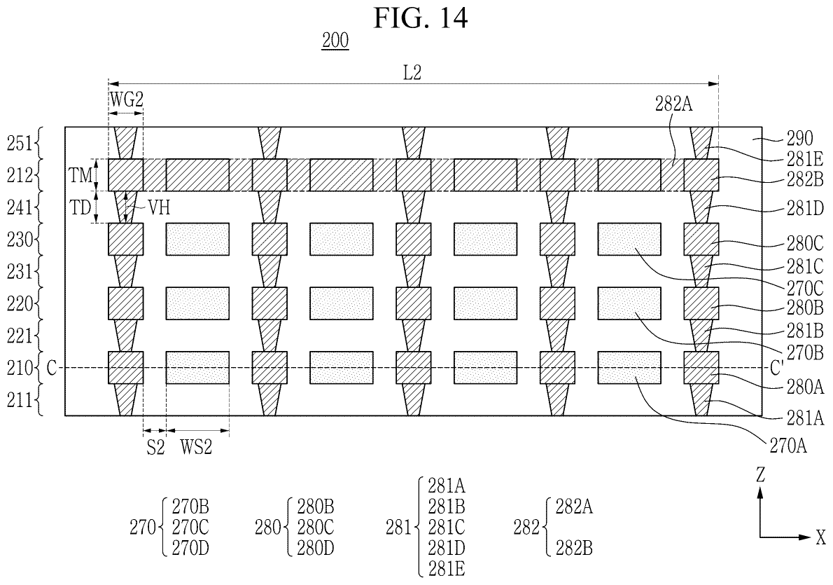

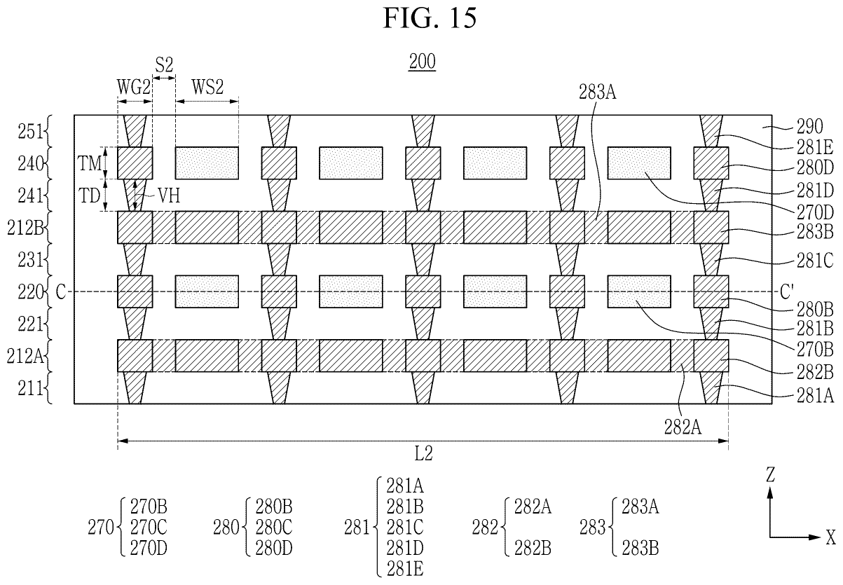

Referring to FIG. 5, FIG. 7, FIG. 9, FIG. 13, FIG. 14, and FIG. 15, a second width WS2 of the signal wire 270 may be greater than a first width WS1 in the first horizontal direction (X direction). In the first horizontal direction (X direction), a fourth width WG2 of ground wire 280 may be equal to a third width WG1. In the first horizontal direction (X direction), the second distance S2 may be greater than a first distance S1. In the first horizontal direction (X direction), a second length L2 may be longer than a first length L1.

In addition to the above description, the description for signal wires 270, ground wires 280, and vias 281 described with respect to FIG. 6, FIG. 8, and FIG. 10 may be applied to the description for signal wires 270, ground wires 280, and vias 281 in FIG. 13, FIG. 14, and FIG. 15.

As described above, although preferable embodiment of the present invention has been explained, the present invention is not limited, and it is possible to implement various modifications within the range of the patent claims and the scope of detailed description of the invention and accompanying drawing, and it is natural that this also belongs to the range of the present invention.

What is claimed is:

1. A semiconductor package comprising:
an interposer including a plurality of signal wires and a plurality of ground wires, wherein the plurality of signal wires and the plurality of ground wires are alternately arranged in a first horizontal direction and extend in a second horizontal direction intersecting with the first horizontal direction; and
a first semiconductor chip and a second semiconductor chip on the interposer, wherein the interposer includes first regions under the first semiconductor chip and under the second semiconductor chip and a second region between the first regions and the plurality of signal wires connect the first semiconductor chip and the second semiconductor chip,
wherein each signal wire among the plurality of signal wires has a first width in the first horizontal direction in the first regions and a second width in the first horizontal direction in the second region, and the second width is greater than the first width.

2. The semiconductor package of claim 1, wherein:
each ground wire among the plurality of ground wires has a third width in the first horizontal direction in the first regions and a fourth width in the first horizontal direction in the second region, and
the third width is equal to the fourth width.

3. The semiconductor package of claim 1, wherein:
each signal wire among the plurality of signal wires is spaced apart by a first distance in the first regions and by a second distance in the second region from an adjacent one of the ground wires among the plurality of ground wires, and
the first distance is equal to the second distance.

4. The semiconductor package of claim 1, wherein:
the interposer includes a first routing layer and a second routing layer on the first routing layer,
the first routing layer includes first signal wires among the plurality of signal wires and first ground wires among the plurality of ground wires, and
the second routing layer includes second signal wires among the plurality of signal wires and second ground wires among the plurality of ground wires.

5. The semiconductor package of claim 4, wherein:
the first signal wires and the second signal wires overlap each other.

6. The semiconductor package of claim 4, wherein:
the first ground wires and the second ground wires overlap each other.

7. The semiconductor package of claim 1, wherein:
each signal wire among the plurality of signal wires routes different signals from others of the signal wires.

8. The semiconductor package of claim 1, wherein:
each signal wire among the plurality of signal wires and each ground wire among the plurality of ground wires be provided in an elongated shape.

9. A semiconductor package comprising:
an interposer including a plurality of signal wires and a plurality of ground wires, wherein the plurality of signal wires and the plurality of ground wires are alternately arranged in a first horizontal direction and extend in a second horizontal direction intersecting with the first horizontal direction; and
a first semiconductor chip and a second semiconductor chip on the interposer, wherein the interposer includes first regions under the first semiconductor chip and under the second semiconductor chip and a second region between the first regions and the plurality of signal wires connect the first semiconductor chip and the second semiconductor chip,
wherein:
each signal wire among the plurality of signal wires has a first width in the first horizontal direction in the first regions and a second width in the first horizontal direction in the second region,
the second width is greater than the first width,
each signal wire is spaced apart by a first distance in the first regions and by a second distance in the second region from an adjacent one of the ground wires among the plurality of ground wires, and
the second distance is greater than the first distance.

10. The semiconductor package of claim 9, wherein:
each ground wire among the plurality of ground wires has a third width in the first horizontal direction in the first regions and a fourth width in the first horizontal direction in the second region, and
the third width is equal to the fourth width.

11. The semiconductor package of claim 9, wherein:
a difference between the second distance and the first distance is smaller than a difference between the second width and the first width.

12. A semiconductor package comprising:
an interposer including
a first signal routing layer including a plurality of first signal wires and a plurality of first ground wires, and
a first ground routing layer including a ground wire structure, and disposed at least one position of upper part and lower part of the first signal routing layer, and
a first semiconductor chip and a second semiconductor chip on the interposer, wherein the interposer include first regions under the first semiconductor chip and under the second semiconductor chip and a second region between the first regions and the plurality of first signal wires connect the first semiconductor chip and the second semiconductor chip,
wherein the plurality of first signal wires and the plurality of first ground wires are alternately arranged in a first horizontal direction and extend in a second horizontal direction intersecting the first horizontal direction, and
wherein each signal wire among the plurality of first signal wires has a first width in the first horizontal direction in the first regions and a second width in the first horizontal direction in the second region, and
wherein the second width is greater than the first width.

13. The semiconductor package of claim 12, wherein:
the interposer further includes a plurality of vias, and
the plurality of vias connect the plurality of first ground wires and the ground wire structure.

14. The semiconductor package of claim 12, wherein:
the interposer further includes a second signal routing layer on the first signal routing layer,
the second signal routing layer includes a plurality of second signal wires and a plurality of second ground wires,
the plurality of second signal wires and the plurality of second ground wires are alternately arranged in the first horizontal direction and extend in the second horizontal direction intersecting with the first horizontal direction,
each of the plurality of second signal wires has a third width in the first horizontal direction in the first regions and a fourth width in the first horizontal direction in the second region, and
the fourth width is greater than the third width.

15. The semiconductor package of claim 14, wherein:
each first signal wire among the first signal wires or each second signal wire among the second signal wires is separated from others of the first signal wires and others of the second signal wires.

16. The semiconductor package of claim 12, wherein:
the ground wire structure is provided in a mesh shape.

17. The semiconductor package of claim 12, wherein:
the ground wire structure includes:
first subsidiary part extending in the first horizontal direction; and
second subsidiary part intersecting with the first subsidiary part and extending in the second horizontal direction.

18. The semiconductor package of claim 17, wherein:
the first subsidiary part has a first length in the first horizontal direction in the first regions and a second length in the first horizontal direction in the second region, and
the second length is greater than the first length.

19. The semiconductor package of claim 12, wherein:
the first semiconductor chip includes at least one of a central processing unit (CPU) and a graphic processing unit (GPU).

20. The semiconductor package of claim 12, wherein:
the second semiconductor chip includes a high bandwidth memory (HBM).
